(19) United States
(12) Patent Application Publication
(10) Pub. No.: US 2004/0009628 A1
(43) Pub. Date: Jan. 15, 2004

(54) Fabrication method of substrate on chip CA ball grid array package

(76) Inventor: Yi-Liang Peng, Hsinchu Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/191,071

(22) Filed: Jul. 10, 2002

(51) Int. Cl. H01L 21/44; H01L 21/48; H01L 21/50

(52) U.S. Cl. 438/107; 438/460; 438/612

(57) ABSTRACT

The present invention discloses a fabrication method of substrate on chip CA BGA package, wherein a chip is installed on a first surface of each substrate unit of a substrate with the front face of the chip attached with the first surface. The area of the substrate units arranged in a matrix array is smaller than that of the chip. Next, a plurality of leads are used to connect the front faces of the chips with second surfaces of the substrate units by wire bonding. Finally, several solder bumps are formed on the second surfaces of the substrate units between the leads. After the dicing step, the obtained package structure conforms to the requirement of real chip scale package. The present invention can also enhance the throughput, achieve better reliability, and lower the cost.

### FIELD OF THE INVENTION

The present invention relates to an IC package technique and, more particularly, to a fabrication method of substrate on chip CA (chip array) ball grid array (BGA) package.

### BACKGROUND OF THE INVENTION

Along with the progress of integrated circuit (IC) technology, the enhancement of levels and functions of electronic products tend to multi-functionality, high speed, large capacity, high density, and light weight. In order to meet these requirements, in addition to advancement of IC fabrication technique, many novel package techniques and materials have been proposed. In the conventional ball grid array (BGA) package, a printed circuit board (PCB) is used as an electronic package substrate. As shown in FIG. 1, the package structure is a substrate 10. A chip 12 is installed at one surface of the substrate 10. Several leads 14 are used to connect the substrate 10 and the chip 12. A molding compound 16 is provided to cover the chip 12 and the leads 14. Solder balls 18 are used at the bottom of the substrate 10 to electrically connect the chip to other electronic devices. Although the BGA package can provide more leads, it is limited by its size, and cannot provide a structure of smaller volume. This is because that much space needs to be reserved for wire bonding for this kind of package structure. Therefore, the size of the substrate ought to be larger than that of the chip. The object of chip scale package thus cannot be achieved. Moreover, because the chip is completely covered by the molding compound, its heat-radiating effect is inferior.

In order to meet the requirement of high-density package devices for the development of more compact electronic products, the wafer level package (WLP) technique has been proposed, wherein packaging is directly performed on a silicon wafer 20, and the silicon wafer 20 is then sliced into a plurality of package structures 24 using slicing paths 22, as shown in FIG. 2. This WLP structure 24 comprises a chip 26. A plurality of solder bumps 28 are disposed on the chip 26. The planar area of the package structure 24 is commensurate with the area of the original chip 26. The WLP technique originates from the above BGA package technique. The only difference is that the size of solder bump is smaller. However, because of the factors like wafer yield, investment of packaging and testing equipments, and degree of maturity, the development of this kind of WLP technique has a bottleneck. Moreover, there are problems in yield test and solder bump contact.

Accordingly, the present invention aims to propose a fabrication method of substrate on chip CA BGA package to resolve the problems in the prior art.

### SUMMARY OF THE INVENTION

The primary object of the present invention is to provide a fabrication method of substrate on chip CA BGA package, whereby the size, thickness, and weight of a fabricated package are smaller to meet the requirement of real chip scale package.

Another object of the present invention is to provide a fabrication method of substrate on chip CA BGA package, which can enhance the throughput, reduce the molding frequency, and lower the cost.

Another object of the present invention is to provide a fabrication method of substrate on chip CA BGA package, which has a better reliability. Moreover, existent CA BGA equipments can be continually used.

Another object of the present invention is to provide a fabrication method of substrate on chip CA BGA package, whereby the size of a fabricated package structure can be flexibly adjusted according to the customer or market requirement to conform to the specifications of existent carriers or clamping apparatuses.

To achieve the above objects, in the present invention, a substrate is first provided. A plurality of substrate units are then arranged thereon in a matrix array. A frame is used to connect the substrate units together. Next, a chip of larger area is installed on a first surface of each of the substrate units with a front face of the chip attached with the first surface. Subsequently, a plurality of leads are used to connect circuit terminals on the front faces of the chips with second surfaces of the substrate units. Finally, several solder bumps are formed on the second surfaces of the substrate units between the leads. After the dicing step, a plurality of substrate on chip CA BGA package structures can be obtained.

The various objects and advantages of the present invention will be more readily understood from the following detailed description when read in conjunction with the appended drawings, in which:

### BRIEF DESCRIPTION OF THE DRAWINGS:

FIG. 1 is a structure diagram of a conventional BGA package;

FIG. 2 is a diagram of a conventional wafer level package;

FIG. 3 is a diagram of a substrate used in the present invention;

FIG. 4 is a diagram showing the installation of chips of the present invention;

FIGS. 5a to 5d are cross-sectional views of packaging steps of substrate units of the present invention; and

FIG. 6 is a structure diagram of another embodiment of the present invention.

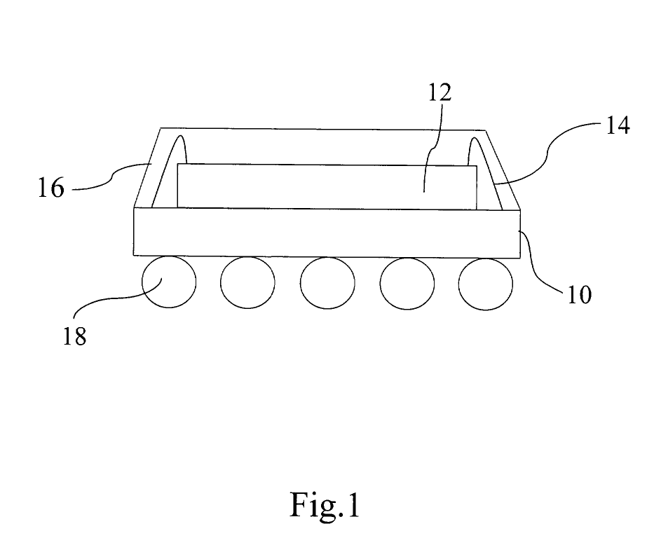

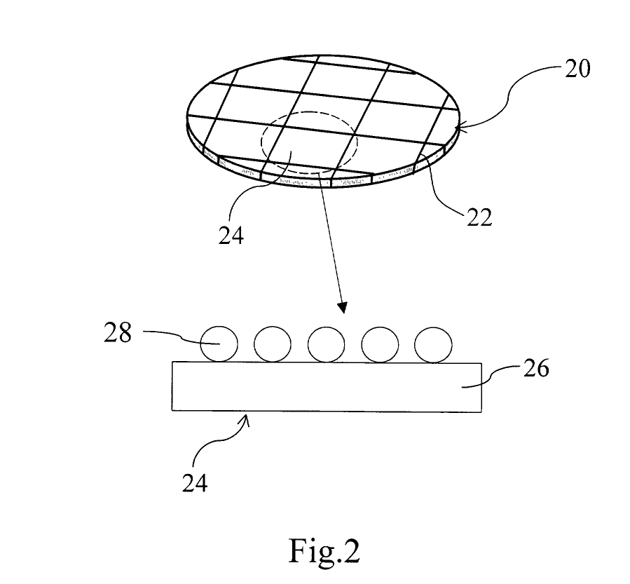

### DETAILED DESCRIPTION OF THE PREFERRED EMBODIMENTS

In the present invention, a plurality of substrate units are disposed on a substrate in advance to directly perform packaging in order thereon so as to form a plurality of substrate on chip CA BGA package structures. Because the area of the chip is larger than that of the substrate unit, the size of the package structure is commensurate with the chip size.

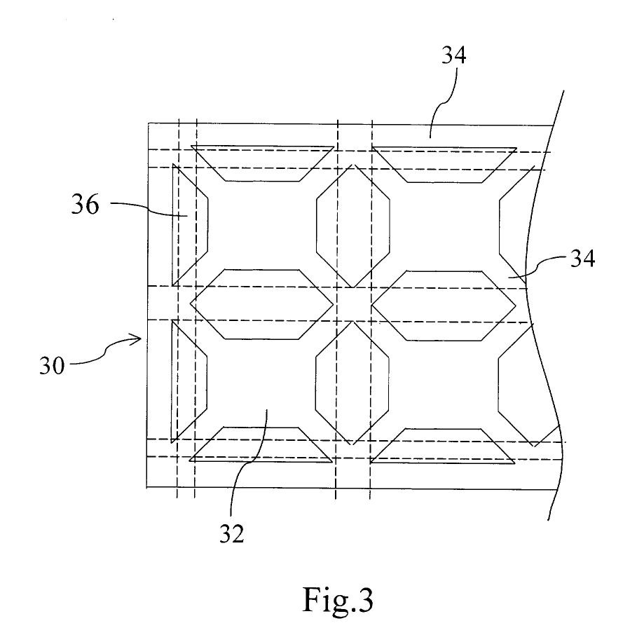

As shown in FIGS. 3 to 5, the fabrication method of the present invention comprises the following steps.

First, as shown in FIG. 3, a semiconductor substrate 30 is provided. A plurality of substrate units 32 arranged in a matrix array are disposed on the substrate 30. The substrate units 32 are connected together using a frame 34 and are integrally formed. A dicing path 36 is preformed between every adjacent two of the substrate units 32. Each of the substrate units 32 has a first surface and a second surface.

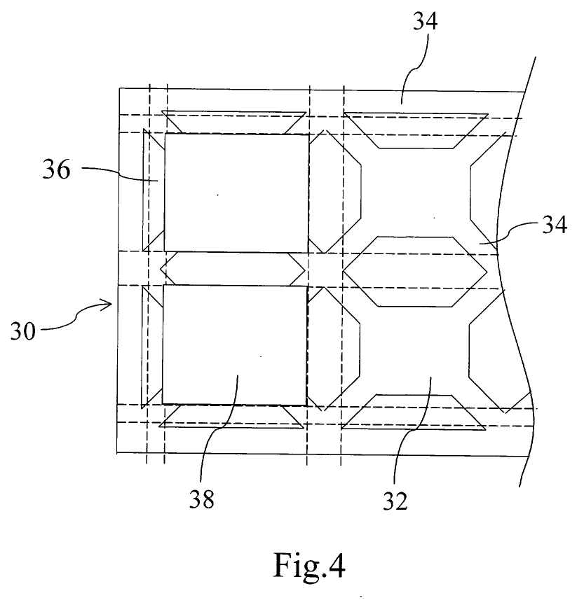

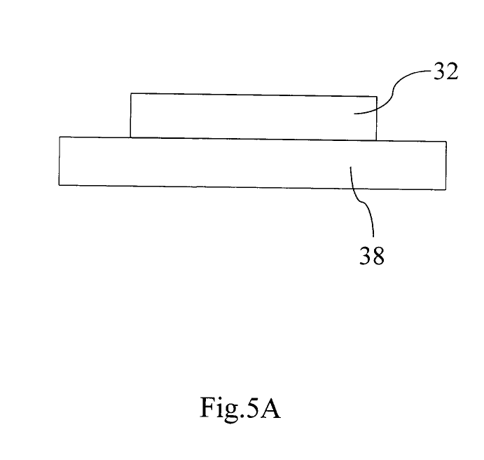

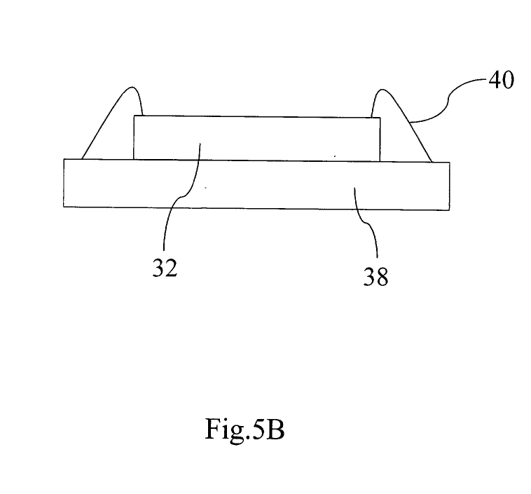

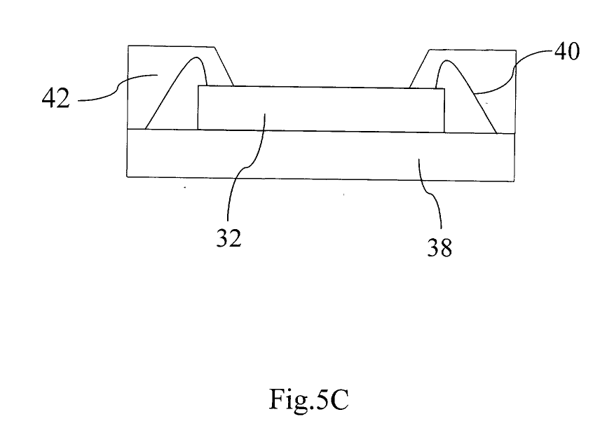

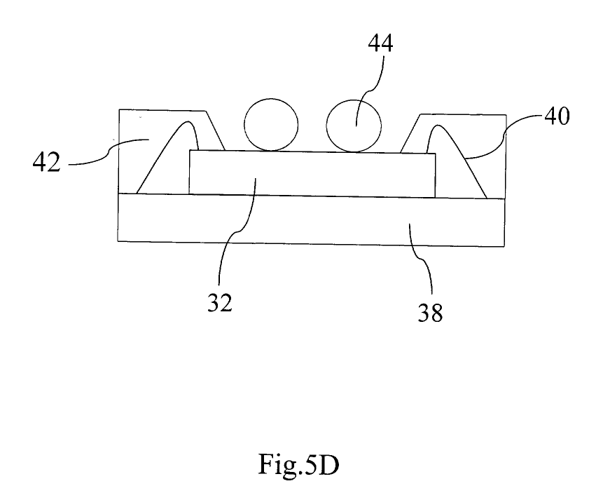

As shown in FIG. 4, a chip 38 is first flipped, and a front face thereof is then installed on the first surface of each of the substrate units 32 of the semiconductor substrate 30 using the die attach technique. With also reference to FIG. 5A, the front face of the chip 38 is attached with the first surface of the substrate unit 32. The size of the chip 38 is larger than that of the substrate unit 32 so that circuit terminals around the front face of the chip 38 can encircle the substrate units 32 and will not contact the substrate units 32 or be pressed.

Next, as shown in FIG. 5B, a plurality of leads 40, usually being gold wires, are used to achieve electric connection between the circuit terminals of the front face of the chip 38 and the second surfaces of the substrate units 32 by wire bonding. As shown in FIG. 5C, an outmost molding compound 42, usually being epoxy resin, is formed by die casting to cover all the leads 40, the exposed front faces of the chips 38, and part of the second surfaces of the substrate units 32 for providing mechanical protection and preventing the chips 38 and the leads 40 from damage due to outside influence (e.g., impact, dust, or moisture).

Finally, as shown in FIG. 5D, 'a plurality of solder bumps 44 are formed on the second surfaces of the substrate units 32 between the leads 40 to be installed onto other devices and achieve electric connection. Subsequently, as shown in FIG. 4, dicing is performed with each of the substrate units 32 as a unit along the dicing paths 36. The whole packaging process is thus finished, and a plurality of substrate on chip CA BGA package structures are obtained.

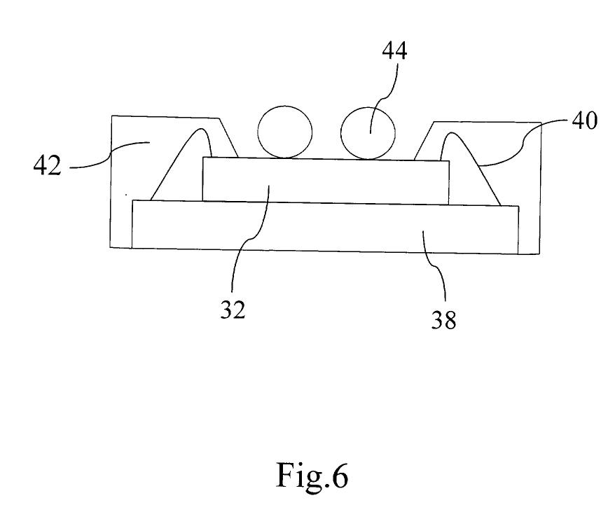

During the dicing step, if the dicing is performed along the edge of the chip, the size of the packaged device is the same as that of the original chip. Besides, in the present invention, the size of the diced product can also be adjusted to meet the customer or market requirements. In other words, the spacing between every adjacent two of the substrate units 32 is enlarged to keep a bit of molding compound 42 beside the chip 38 after the dicing step, as shown in FIG. 6. Thereby, the size of the package structure can be flexibly adjusted according to the molding compound to meet the requirements (e.g., the customer continues using existent carriers or clamping apparatuses).

Additionally, in the present invention, the packaged product can be kept to have the same size as the original chip after dicing. The rate of use of the substrate can thus be increased to lower the substrate cost. Moreover, the present invention can also design the substrate in matrix way to enhance the throughput, reduce the molding frequency, and thus lower the cost.

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

I claim:

1. A fabrication method of substrate on chip CA ball grid array package comprising the steps of:
providing a substrate whereon a plurality of substrate units arranged in a matrix array are disposed, each of said substrate unit having a first surface and a second surface, said substrate units being connected together using a frame;
installing a chip on said first surface of each of said substrate units with a front face of said chip attached with said first surface, the area of said chip being larger than that of said substrate unit;
connecting a plurality of leads from circuit terminals of the front faces of said chips to said second surfaces of said substrate units by wire bonding; using a molding compound to cover said leads and the front faces of said chips; and
forming several solder bumps on said second surfaces of said substrate units between said leads.

2. The fabrication method of substrate on chip CA ball grid array package as claimed in claim 1, wherein dicing is performed with each of said substrate units used as a unit after the step of forming said solder bumps.

3. The fabrication method of substrate on chip CA ball grid array package as claimed in claim 1, wherein a dicing path is disposed between every adjacent two of said substrate units.

4. The fabrication method of substrate on chip CA ball grid array package as claimed in claim 1, wherein said molding compound is epoxy resin.

5. The fabrication method of substrate on chip CA ball grid array package as claimed in claim 2, wherein the size of the whole package structure can be flexibly adjusted according to said molding compound during the dicing step.
